(19) United States
(12) Patent Application Publication
(10) Pub. No.: US 2005/0161707 A1
(43) Pub. Date: Jul. 28, 2005

(54) Esd-robust power switch and method of using same

(75) Inventor: Jan Dikken, Nijmegen (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N.V., BA Eindhoven (NL)

(21) Appl. No.: 10/512,728

(22) PCT Filed: Mar. 19, 2003
(86) PCT No.: PCT/IB03/01017

(30) Foreign Application Priority Data
Apr. 29, 2002 (EP) 02076694.5

(51) Int. Cl. H01L 29/76

(52) U.S. Cl. 257/213

(57) ABSTRACT

A power switch comprising a field effect transistor (FET) including an active area in a semiconductor body, a channel formed in said active area and having a periodic structure, source diffusion zones and drain diffusion zones in the active area, a source diffusion zone being separated from a drain diffusion zone by a half period of the periodic structure of the channel, and each source diffusion zone having a source contact, and each drain diffusion zone having a drain contact. The source contacts and the drain contacts are aligned in a row in a direction transverse to the plane of symmetry of the channel. Current paths have substantially the same series resistance between a source contact and a drain contact associated with a source diffusion zone and a drain diffusion zone which alternate with each other. The ESD-robust power switch is very compact and suited for high voltages.

The invention relates to a power switch comprising a field effect transistor (FET) including
an active area in a semiconductor body,
a channel formed in said active area and having a periodic structure,
source diffusion zones and drain diffusion zones in the active area, a source diffusion zone being separated from a drain diffusion zone by a half period of the periodic structure of the channel, and
each source diffusion zone having a source contact, and each drain diffusion zone having a drain contact.

The invention also relates to a method of using the power switch in accordance with the invention.

U.S. Pat. No. 6,002,156 discloses such a MOSFET that protects an integrated circuit (IC) against electrostatic discharge (ESD)/electrostatic overstress (EOS). The integrated circuit is an IC with MOS transistors. The most common protection circuit for ICs with MOS transistors is an NMOS transistor whose drain is connected to the pin to be protected of the IC and whose source and gate are connected to ground. The protection level can be adjusted through the width of the channel of the NMOS. Under voltage conditions, the parasitic bipolar transistor of the NMOS transistor is the dominant current path between the pin to be protected and ground. This bipolar transistor operates in the snap-back region when the pin voltage is positive with respect to ground.

The known MOSFET has a compact layout. The channel has a meandering shape. The part of the meandering channel that is repeated in the periodic pattern is a period. As a result of the meandering structure of the channel, the width of the channel per unit area is increased. Said increase of the width of the channel per unit area has the advantage that the current level can be higher as a result of the ESD protection. Alternatively, said ESD protection may take up less space. In the known embodiment, the gain in width per unit area is maximally 40%.

A drawback of the known MOSFET resides in that owing to the compact layout only a low series resistance in the diffusion zones is possible, so that the transistor is unsuitable to deal with high voltage peaks. In addition the MOSFET has a high gate resistance as a result of which the device cannot switch rapidly and the gate voltage cannot be controlled.

To test the ESD robustness of the device, use is generally made of the Human Body Model (HBM) and the Charged Device Model (CDM). In the HBM, simulation takes place of the discharge that may occur when a person touches a device. The human body can be represented by a capacitor of 100 pF which is charged to a specified voltage. The capacitor is subsequently discharged over the device and over a resistor of 1500 Ohm.

CDM simulates a charged device that makes contact with a metal base area, which occurs typically in the case of automated handling equipment.

In general, the dominant failure mechanism of an NMOS protection device operating in snap-back is second breakdown. Second breakdown is a phenomenon that induces thermal runaway into the device when the decrease of the impact ionization current is negligible with respect to thermal generation of charge carriers. Second breakdown occurs in the case of a high current through the device as a result of self-heating. The time that is necessary to heat up the structure to the critical temperature at which second breakdown occurs depends on the device layout and on the stress power distribution over the device.

It is an object of the invention to provide a power switch of the type described in the opening paragraph, which is more robust to voltage peaks.

In the case of the power switch in accordance with the invention, this object is achieved in that the source contacts and the drain contacts each form a row in a direction transverse to the plane of symmetry of the channel, current paths being subject to substantially equal series resistance between a source contact and a drain contact associated with a source diffusion zone and a drain diffusion zone which alternate with each other.

The series resistance makes sure that if a part of the transistor goes into snap-back and causes the drain voltage to be reduced, the voltage that can be built up in the case of an increasing current across the series resistance is sufficient so that the trigger voltage for the snap-back of another part of the transistor can be achieved again without the current density locally increasing to destructive values.

As a result of equal series resistances in the current paths between a source contact and a drain contact of each diffusion zone, the current is distributed more uniformly over the entire active area. The improved spread of the ESD current leads to a more uniform distribution of the heat, as a result of which local heating is reduced and second breakdown occurs less readily. In comparison with the prior art, the FET is more suitable to deal with higher voltage peaks of typically 2000-8000 V (HBM) and is also more suitable to drain a higher ESD current to ground.

Preferably, the row of source contacts and the row of drain contacts are situated outside an area that is clamped by the periodic structure of the channel. By spacing the contacts relatively far apart, a series resistance is created. The series resistance between the source and drain contacts can be accurately adjusted through the distance between the row of source contacts and the row of drain contacts. In order not to adversely affect the switching behavior of the FET, the series resistance is only a small percentage of the on-resistance of the transistor. However, to withstand high voltage peaks and to be capable of safely draining to ground the associated ESD current, the series resistance must be large enough. In practice, the series resistance is typically of the order of 10% of the on-resistance of the transistor. The series resistance precludes instability and destruction of the device by second breakdown.

The row of source contacts and the row of drain contacts are staggered in a direction of the row over a distance equal to a half period of the channel.

As a result a symmetric layout of the FET is obtained, so that the FET can be readily scaled to higher voltages and higher ESD currents.

The specific layout of the FET serves to obtain a uniform distribution of the stress current and also to obtain a very compact FET. The layout is such that a further channel is present which is the mirror image of the channel upon reflection in a plane extending at least substantially perpendicularly to the semiconductor body and intersecting the row of source contacts or the row of drain contacts. The further channel is electrically parallel-connected to the channel, so that the layout is suitable to drain relatively high currents of several amperes to ground. The higher the voltage peaks to be dealt with by the FET, the more electrically parallel-connected channels are necessary. The symmetric layout enables proper scaling in combination with a comparatively small active surface of the FET. It is very advantageous that the space occupied by the FET is reduced as compared to the prior art. Particularly with ICs having a comparatively small surface of several millimeters, such as DC-DC converters, much space can be saved because the FET occupies a substantial part of the chip surface.

As the source and drain contacts are centered in the source and drain diffusion zones enclosed by the channel and the further channel, the current paths between a source contact and a drain contact are identical for all periods of the channel.

It is possible that the source diffusion zones are of a first conductivity type and are mutually separated by a zone of a second conductivity type. However, the source diffusion zones are electrically interconnected, for example, by means of a metallization pattern. As the source diffusion zones are electrically interconnected, an ESD event triggers a source-zone cascade. By virtue thereof, snap-back does not occur locally but over a large surface area. The current is distributed more uniformly over the surface of the FET.

A plurality of contacts may be present per source or drain zone. As a result, the influence of contact resistances is reduced.

In general ICs having MOS or BiCMOS transistors are protected by a MOSFET. The ESD device and the MOS transistors of the IC are manufactured simultaneously.

On the active area of the semiconductor body there is a dielectric and a gate structure. The gate is electrically insulated from the semiconductor body by the dielectric. The gate is used as a masking for the implantations of the source and drain zones. After diffusion of the source and drain zones, the channel is formed below the gate.

As the channel is self-aligned with respect to the gate, the channel follows the periodic structure of the gate.

In general, the gate is formed from a layer of highly doped polysilicon. The sheet resistance of the gate can be reduced typically by a factor of 50 by using silicidized polysilicon instead of non-silicidized polysilicon. This large reduction of the gate resistance precludes the so-termed gate lifting. Owing to the overlap capacitance between the drain and the gate there is a risk of gate-potential lifting at high drain voltage changes. The potential of the gate may be lifted, for example, upon switching another transistor (such as a PMOS transistor) in an output buffer. As a result of switching-off, a dV/dt develops on the FET which causes the gate voltage to be lifted. A short RC delay as a result of a small gate resistance additionally has the advantage of a short RC delay enabling rapid switching of the FET. At a low gate resistance the charge is directly drained to ground and the gate voltage remains substantially 0 V. A substantial advantage of a silicidized gate resides in that no special protection mask is necessary during silicidation of the ESD protection. As a result, one masking step can be saved. In addition, the extra tolerances built in for aligning the mask are no longer necessary. Without said protection mask, both space and costs can be saved.

A further reduction of the gate resistance is achieved in that the gate, like the channel, has a mirror image forming a further gate, each period of the gate being electrically parallel-connected to a period of its mirror image.

Preferably, the connection between a period of the gate and its mirror image is made of a material which is identical to that used for the gate and the further gate. The connections are formed concurrently with the definition of the gate and the further gate. A very suitable material is polysilicon with a high doping of for example As, P, Sb or B.

In a preferred embodiment, the periodic structure of the channel is meander-shaped.

As a result of the meander shape of the channel, the width of the channel per unit area is increased. Also the length and the width of the channel are accurately defined.

In accordance with an advantageous method, the power switch in accordance with the invention can be electrically connected by means of an NMOS transistor in a grounded gate configuration, wherein the semiconductor body comprises a low-impedance substrate which is electrically connected to ground. In the case of an ESD voltage pulse, the potential on the drain can freely fluctuate relative to the substrate, as a result of which a substantial reduction of the parasitic drain-substrate capacitance is achieved.

These and other aspects of the power switch in accordance with the invention will be elucidated with reference to the embodiment(s) described hereinafter.

In the drawings:

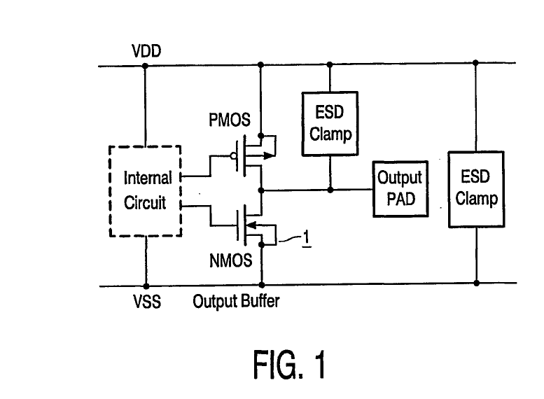

FIG. 1 diagrammatically shows the position of the power switch in accordance with the invention on a chip;

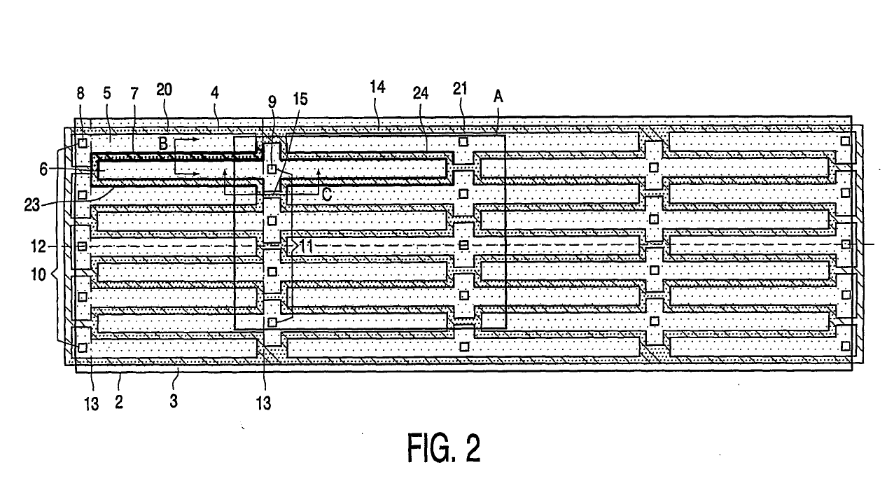

FIG. 2 is a plan view of an embodiment of the power switch in accordance with the invention;

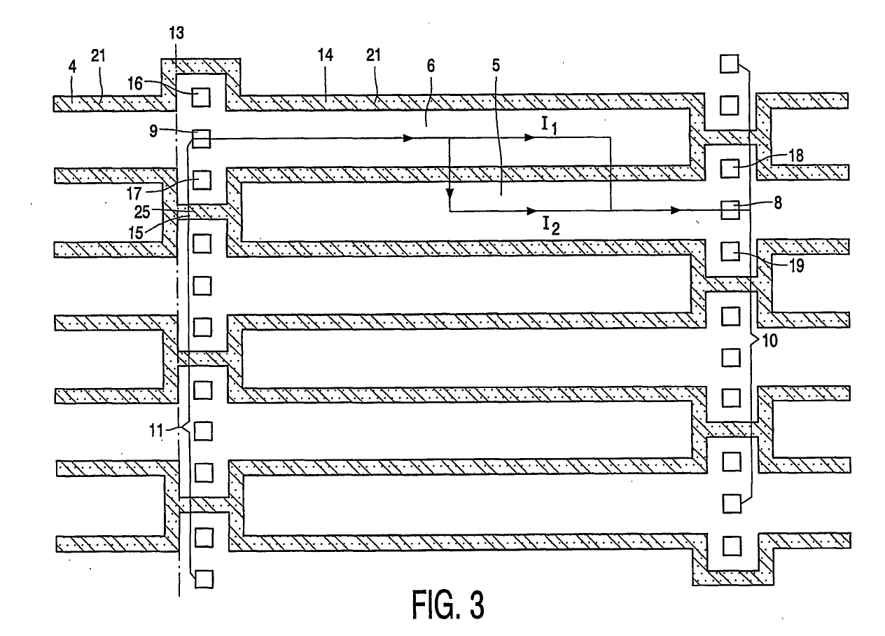

FIG. 3 shows zone A in FIG. 2 on an enlarged scale;

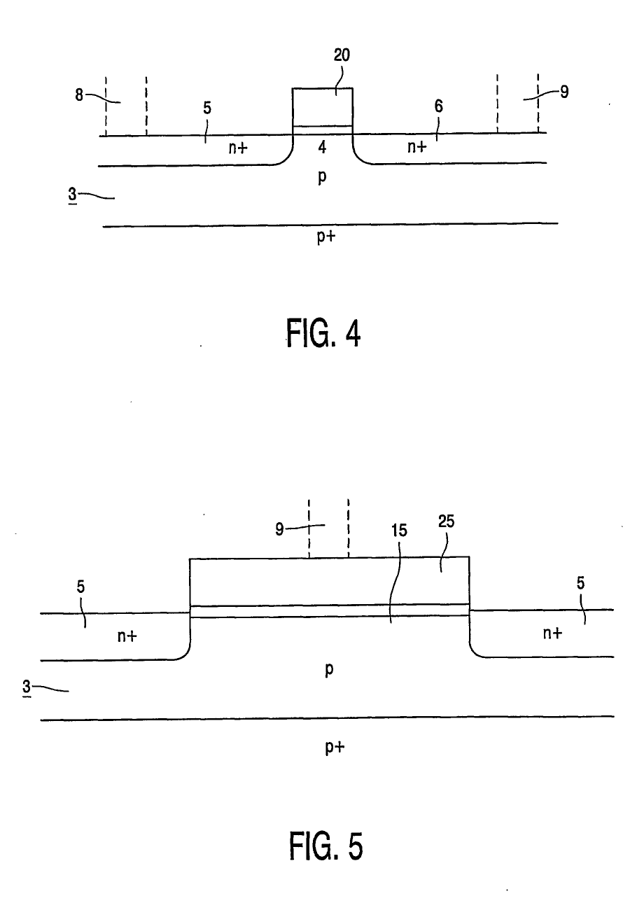

FIG. 4 is a cross-sectional view through B-B in FIG. 2;

FIG. 5 is a cross-sectional view through C-C in FIG. 2;

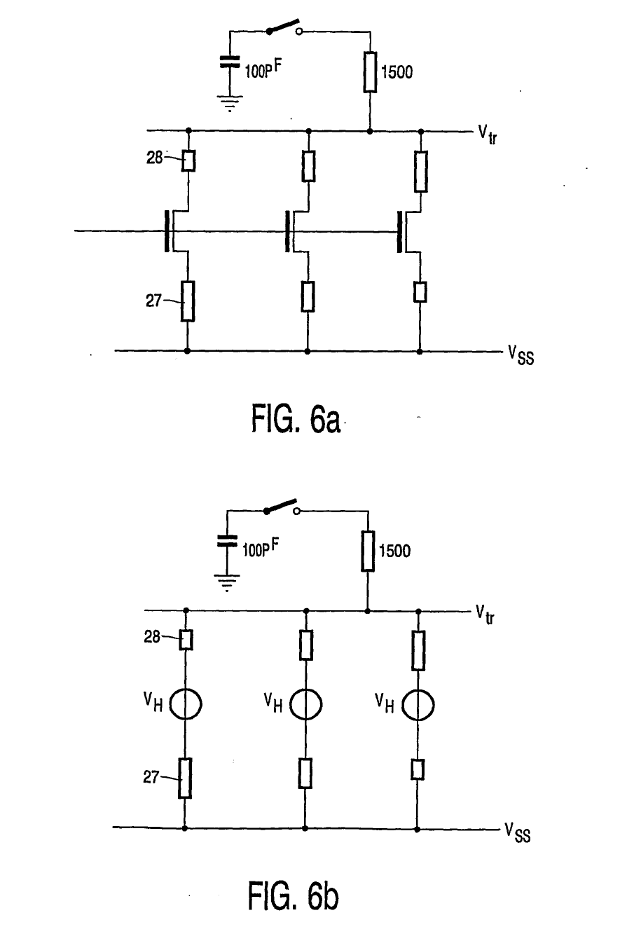

FIG. 6 diagrammatically shows the power switch in accordance with the invention in a test setup according to the Human Body Model;

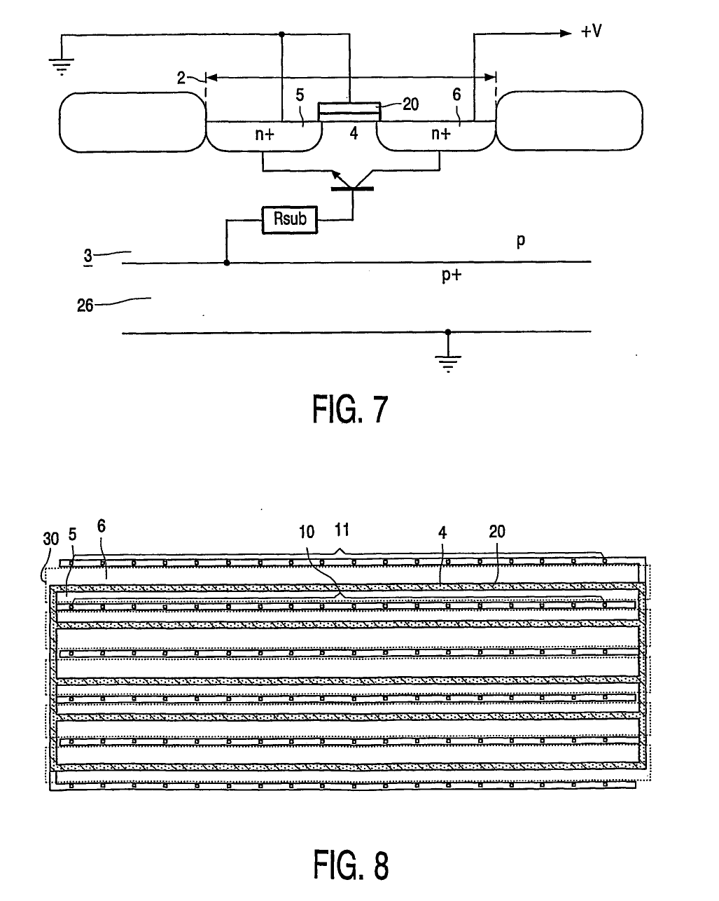

FIG. 7 diagrammatically shows a grounded gate NMOS device configuration;

FIG. 8 shows an embodiment of the power switch in accordance with the prior art;

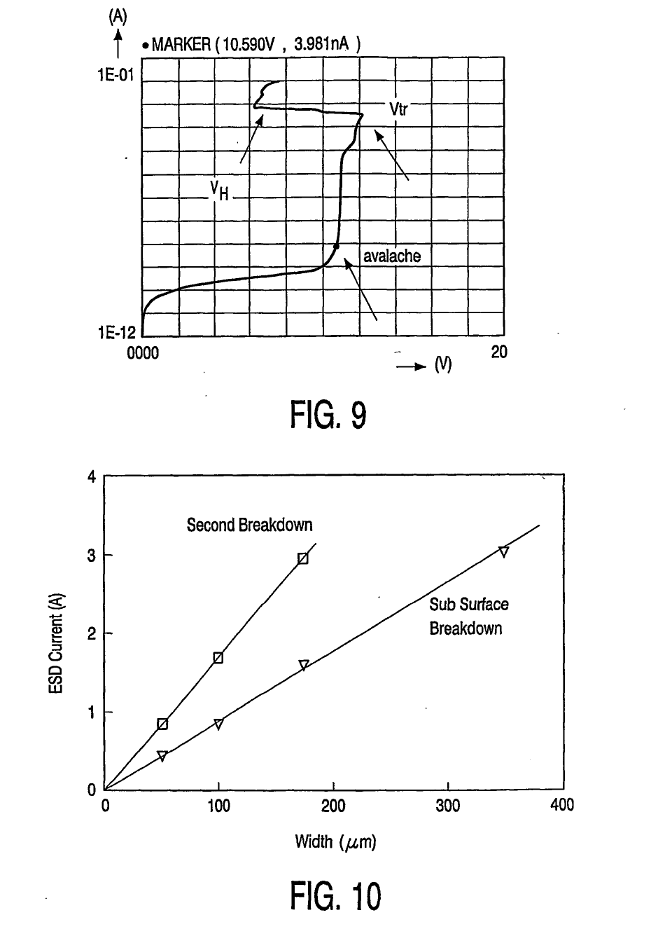

FIG. 9 shows an avalanche breakdown characteristic;

FIG. 10 graphically shows the influence of the width of the gate on the ESD current;

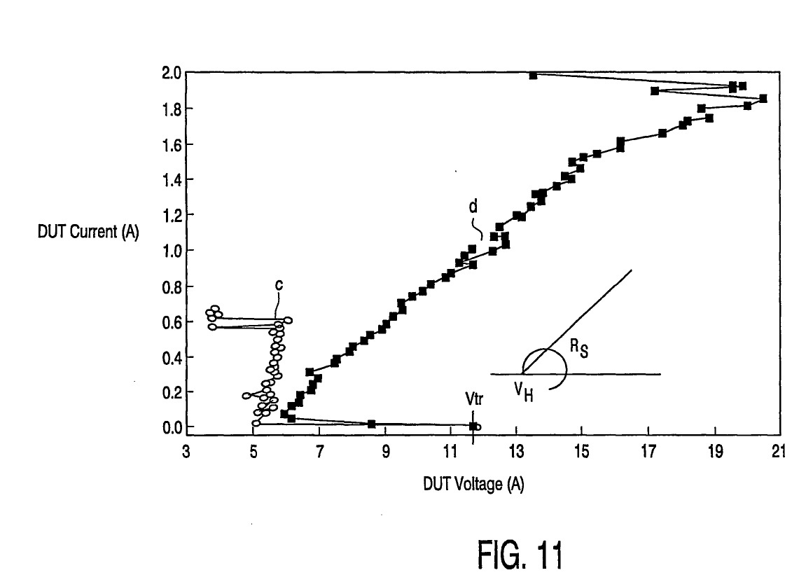

FIG. 11 graphically shows the influence of silicidation on the ESD current.

The NMOS transistor shown in FIG. 1 is a power switch in an output buffer. The NMOS also serves to limit the voltage that may develop at the output of the integrated circuit as a result of an undesirable, high voltage peak. The NMOS transistor is ESD-robust. In the case of an ESD discharge the NMOS transistor can suitably be used to remove the ESD current via a known path. In the case of comparatively small ICs, such as DC-DC converters having a surface area of only a few mm, a considerable percentage of the surface (as high as 50%) is occupied by the ESD protection.

The power switch in accordance with the invention, as shown in FIG. 2, is a MOSFET 1.

The FET 1 comprises an active area 2 in a semiconductor body 3, a channel 4 formed in the active area 2 and having a periodic structure, and source diffusion zones 5 and drain diffusion zones 6 in said active area 2.

A source diffusion zone 5 is separated from a drain diffusion zone 6 by a half period 7 of the periodic structure of the channel 4. Each source diffusion zone 5 has a source contact 8 and each drain diffusion zone 6 has a drain contact 9.

The source contacts 8 and drain contacts 9 each form a row 10, 11 in a direction transverse to the plane of symmetry 12 of the channel. Between a source contact 8 and a drain contact 9 associated with a source diffusion zone 5 and a drain diffusion zone 6 which alternate with each other, current paths are subject to an at least substantially equal series resistance.

In the embodiment shown in FIG. 2, the periodic structure of the channel is a meander. The channel of the MOSFET has a length of 0.5 μm. The overall width of the channels is 600 μm. The meandering channel has a period of 4.2 μm. The row of source contacts 10 are situated on the left-hand side of the first meandering channel. The row of drain contacts 11 on the right-hand side of the first channel are shifted by 2.1 μm with respect to the row of source contacts 10. If an ESD event causes a voltage to be applied to the drain contacts, then an ESD current starts flowing between the source and the drain. The current paths between a source 8 and a drain 9 contact associated with a period 7 of the meander cross the channel 4 transversely at different locations. As the series resistance for each current path is the same, the current distribution over a period 7 of the channel is very uniform.

FIG. 3 diagrammatically shows the current paths I₁, I₂ between a source contact 8 and a drain contact 9. The row of source contacts 10 and the row of drain contacts 11 are situated outside the area 13 that is clamped by the periodic structure of the channel 4. In the embodiment shown, the series resistance in each current path I₁, I₂ of the source and drain zones jointly amount to approximately 8 times the sheet resistance of the source and drain diffusion zones.

The layout of the FET in FIG. 2 is very compact as a result of the high degree of symmetry. There is a further channel 14 that is the mirror image of the channel 4 upon reflection in a plane that extends at least substantially perpendicularly to the semiconductor body 3 and intersects the row of source contacts 10 or the row of drain contacts 11. As the further channel 14 is electrically parallel-connected to the channel 4, comparatively high ESD currents can be drained to ground.

The source 8 and drain 9 contacts are centered in the source 5 and drain 6 diffusion zones which are enclosed by the channel 4 and the further channel 14. The shortest distance from the source or drain contact to the meandering channel is only 1 μm. Unlike the prior art, where the distance from the drain contact to the channel is 4.5 μm, in the embodiment shown only 1 μm is necessary. This means an enormous saving in active surface area.

The dotted squares in FIG. 3 indicate that a plurality of contacts 16, 17, 18, 19 may be present per source or drain zone. The minimum distance to the meandering channel is determined by the design rules (0.6 μm in this example).

The gate 20 is electrically insulated from the channel 4. The channel 4 below the gate 20 has the same periodic structure as the gate 20.

Both the source 5 diffusion zones and the drain 6 diffusion zones are electrically interconnected by an interdigitated metallization pattern interconnecting, respectively, the row of source contacts 10 or the row of drain contacts 11.

FIG. 4 is a cross-sectional view of the NMOSFET. On a highly doped p-type substrate an active area 2 is formed in the semiconductor body 3 which is surrounded by insulating material, such as SiO₂. The active area 2 is doped with boron. On the surface of the semiconductor body there is provided a gate dielectric of 10 nm SiO₂. Subsequently, a layer of polysilicon having a thickness of 250 nm is deposited. The layer of polysilicon is patterned and forms the gate 20. The shallow source and drain diffusion zones forming an extension of the source 5 and drain 6 are implanted with p ions in a dose of 4e13 at/cm² with an energy of 25 keV. The source 5 and drain 6 diffusion zones are implanted with As ions in a dose of 4e15 at/cm² at an energy of 100 keV. The sheet resistance of the non-silicidized n-type As zone is 55 Ohm/square after outdiffusion.

The polysilicon gate 20 is doped concurrently with the source and drain diffusion zones. The sheet resistance of the As-doped polysilicon is 135 Ohm/square. After spacer formation next to the polysilicon gate 20, a Ti/TiN multilayer is provided in a thickness of 30 nm/25 nm. During a rapid thermal process (RTP) there is formed in N₂ at 730° C. in 20 seconds approximately 70 nm TiSi₂ on the gate and on the source and drain diffusion zones. The sheet resistance of the silicidized polysilicon is 2.3 Ohm/square. The sheet resistance of the silicidized source and drain diffusion zones is 2.3 Ohm/square.

The contacts to the active area are made using W plugs in a manner known to those skilled in the art. The source contacts are interconnected by means of an Al metallization pattern. The drain contacts are also interconnected by means of an Al metallization pattern, both metallization patterns forming a finger structure.

In FIG. 5, the connection 25 between a period 23 of the gate and its mirror image 24 is shown for the NMOSFET. The connection is made concurrently with the gate 20 and the further gate 21 from polysilicon doped with As in a concentration of 4e15 at/cm². The polysilicon gate 20, 21 are doped concurrently with the source and drain diffusion zones. The sheet resistance of the As-doped polysilicon is 135 Ohm/square. The n-type source 5 diffusion zones are electrically insulated from each other by a p-epi area 15.

In a Human Body Model test setup shown in FIG. 6a, the NMOS transistor is tested for ESD robustness. A voltage of 2000-8000 V is applied across the 100 pF capacitance. The voltage is discharged across the 1.5 kOhm resistor and the NMOS transistor. At a certain voltage, i.e. the trigger voltage Vtr, the avalanche current is large enough, as a result of breakdown of the drain-substrate junction, to turn on the bipolar transistor. As soon as the parasitic bipolar transistor goes into conduction, snap-back occurs causing the voltage to decrease to the so-termed hold voltage V_{H}. FIG. 6b diagrammatically shows the series resistances in the source and drain diffusion zones of different current paths. The sum of the series resistances between a source and a drain contact is, in the embodiment shown in FIG. 2, approximately 8 times the sheet resistance of the silicidized source and drain diffusion zones. It is schematically shown that, dependent upon the current path, the source diffusion resistance 27 may exceed the drain diffusion resistance 28. The essence of the invention is that the sum of the source diffusion resistance 27 and the drain diffusion resistance 28 is at least substantially equal for all current paths. As soon as the hold voltage V_{H} is reached, it does not matter, from an electrical point of view, whether the diffusion resistance is present in the source diffusion zone or in the drain diffusion zone.

The sum of the resistances in the silicidized diffusion zones corresponds to a series resistance of 8*2.3 Ohm=18.4 Ohm. In the embodiment shown, there are 8*4=32 sections, so that the series resistance of the transistor is approximately 600 mOhm.

In the Human Body Model test, the NMOS transistor is robust to voltages >2000 V. As regards ESD sensitivity, the transistor belongs to class 2 of the Human Body Model. The resistance of the transistor is 5 Ohm in the on-state and the series resistance is 600 mOhm. The total surface of the active area is 2043 squares.

In operation, the NMOSFET is connected in a grounded NMOS configuration as shown in FIG. 7. It is remarkable that instead of a p-well contact as used in conventional structures, a highly doped p-type substrate of 0.01 Ohm/cm is connected to ground as the rear side contact. The contacting of the p-type substrate has substantial advantages in comparison with the p-well. In the first place, the space occupied by the p-well contacts is saved. What is more important is that also the parasitic capacitance of the drain to the substrate is absent. The potential of the drain zones can freely fluctuate with respect to the substrate. As a result of the comparatively large surface of the drain diffusion zones, this means that a substantial reduction of the parasitic drain-substrate capacitance is achieved.

The layout of the FET shown in FIG. 2 is much more compact than the conventional finger structure. FIG. 8 shows a conventional finger structure which is ESD robust to voltage peaks between 2000-5000 V. The width of the channel of the transistor is 500 μm. The resistance of the transistor in the on-state is 6 Ohm and the series resistance is 600 mOhm.

In the conventional finger structure additional series resistance is created by means of an additional mask 30 to block the silicidation of the source, the gate and the drain. The protection mask overlaps the polysilicon gate by 4 μm on the drain side and by 1.7 μm on the source side. This not only takes up much space but also causes the resistance of the gate to be increased by a factor of 50. As a result, the gate of a large transistor may be locally lifted if the voltage on the drain exhibits a steeply increasing slope. This may lead to a large, undesirable current peak that may seriously interfere with the operation of the chip. This in turn requires additional layout measures leading to a further increase of the surface. To deal with voltage peaks in the range between 2000-5000 V, the surface of the conventional finger structure is 4145 squares.

The power switch in accordance with the invention, which has 2043 squares of active surface, is much more compact. Relative to the conventional structure, a 50% saving of surface is obtained.

The uniformity of the current in the layout in accordance with the invention is substantially improved as compared to the conventional finger structure. In the conventional finger structure each one of the fingers might be turned on if the voltage rises to the trigger voltage. After a finger starts conducting the bipolar npn transistor and is fixed at the snap-back voltage, the pad voltage is built up as a result of the series resistance. When the voltage again reaches Vtr the next finger is turned on, etc., until all the fingers are turned on or the failure current is reached, whichever of the two occurs first. In general, the maximum current for failure is reached first and the number of fingers that are really turned on vary substantially.

The avalanche breakdown characteristic for the NMOSFET in accordance with the first embodiment is shown in FIG. 9. As a result of the high positive drain voltage, avalanche multiplication occurs in the depletion zone of the drain junction. As the surface concentration of the drain exceeds that in the bulk, typically 1e20 at/cm², breakdown occurs at the edge of the drain junction. The threshold voltage Vtr for breakdown as a result of avalanche multiplication is approximately 12 V. As a result of the substrate current the source-substrate diode becomes conducting. The parasitic bipolar transistor is turned on. As a result of the conduction by the bipolar transistor the electrons are led to the drain. The hold voltage V_{H} is approximately 6 V. After the npn is turned on and keeps the voltage at approximately 6 V, the voltage of the pad can increase to the 12 V trigger voltage as a result of the series resistance.

FIG. 10 shows that the ESD current depends substantially linearly on the width of the channel. Breakdown at the surface of the inhibited drain-substrate junction (curve a) occurs sooner than breakdown caused by self-heating (curve b).

FIG. 11 shows the influence of silicidation on the ESD current. As the sheet resistance of the drain is substantially reduced from 55 Ohm in the non-silicidized case to 2.3 Ohm in the case where 70 nm TiSi₂ is formed, only a maximum current of 0.6 A can be drained to ground by the transistor (curve c). Without silicide, the maximum current is approximately 2 A (curve d).

1. A power switch comprising a field effect transistor (FET) including
an active area in a semiconductor body,
a channel formed in said active area and having a periodic structure,
source diffusion zones and drain diffusion zones in the active area, a source diffusion zone being separated from a drain diffusion zone by a half period of the periodic structure of the channel, and
each source diffusion zone having a source contact, and each drain diffusion zone having a drain contact, characterized in that the source contacts and the drain contacts each form a row in a direction transverse to the plane of symmetry of the channel, current paths being subject to substantially equal series resistance between a source contact and a drain contact associated with a source diffusion zone and a drain diffusion zone which alternate with each other.

2. A power switch as claimed in claim 1, characterized in that the periodic structure of the channel clamps an area, the row of source contacts and the row of drain contacts being situated outside the clamped area.

3. A power switch as claimed in claim 1, characterized in that the row of source contacts and the row of drain contacts are staggered in a direction of the row over a distance equal to a half period of the channel.

4. A power switch as claimed in claim 1, characterized in that a further channel is present which is the mirror image of the channel upon reflection in a plane extending at least substantially perpendicularly to the semiconductor body and intersecting the row of source contacts or the row of drain contacts, and said further channel being electrically parallel-connected to the channel.

5. A power switch as claimed in claim 3, characterized in that the source and drain contacts are centered in the source and drain diffusion zones enclosed by the channel and the further channel.

6. A power switch as claimed in claim 1, characterized in that the source diffusion zones are of a first conductivity type and are mutually separated by a zone of a second conductivity type.

7. A power switch as claimed in claim 1, characterized in that a plurality of contacts are present per source or drain zone.

8. A power switch as claimed in claim 1, characterized in that above the channel there is a gate that is electrically insulated from the channel, said gate following the periodic structure of the channel.

9. A power switch as claimed in claim 8, characterized in that the gate is silicidized.

10. A power switch as claimed in claim 8, characterized in that the gate, like the channel, has a mirror image forming a further gate, a period of the gate being electrically parallel-connected to a period of its mirror image.

11. A power switch as claimed in claim 8, characterized in that the connection between a period of the gate and its mirror image is made of a material which is identical to that used for the gate and the further gate.

12. A power switch as claimed in claim 1, characterized in that the periodic structure is a meander.

13. A method for using the power switch as claimed in claim 1, wherein the FET is an NMOS which is electrically connected in a grounded gate configuration, and wherein the semiconductor body comprises a low-impedance substrate which is electrically connected to ground.
